(19) United States
(12) Patent Application Publication
(10) Pub. No.: US 2025/0085368 A1
(43) Pub. Date: Mar. 13, 2025

(54) ISOLATED RESONANT POWER SUPPLY CIRCUIT, MAGNETIC RESONANCE IMAGING SYSTEM, AND AIR-CORE TRANSFORMER

(71) Applicant: GE Precision Healthcare LLC, Waukesha, WI (US)

(72) Inventors: Hong Gu, Beijing (CN); Haiyuan Sun, Beijing (CN); Yue Ma, Beijing (CN); Yalu Wu, Beijing (CN); Chunlai Xiao, Beijing (CN)

(21) Appl. No.: 18/882,443

(22) Filed: Sep. 11, 2024

(30) Foreign Application Priority Data
Sep. 13, 2023 (CN) 202311181541.4

(51) Int. Cl. G01R 33/36; G01R 33/385; H01F 27/28; H02M 1/00; H02M 7/48

(52) U.S. Cl. CPC G01R 33/3614; G01R 33/3852; H01F 27/2804; H02M 1/0058; H02M 7/4815

(57) ABSTRACT

An isolated resonant power supply circuit, a magnetic resonance imaging system, and an air-cored transformer is provided. The isolated resonant power supply circuit is disposed within a scan room of a magnetic resonance imaging system. The isolated resonant power supply circuit includes: an inverter circuit, a resonant transformer circuit, and a rectifier circuit. The inverter circuit is connected to the resonant transformer circuit and is used for converting inputted direct current power into alternating current power and outputting the same to the resonant transformer circuit. The resonant transformer circuit is used for performing resonant conversion and transformation on the alternating current power, and then output the same to the rectifier circuit. The rectifier circuit is used for rectifying an alternating current output voltage outputted by the resonant transformer circuit into a direct current voltage for output, so as to supply power. The resonant transformer circuit comprises a variable capacitance circuit and an inductor, and by changing an input voltage of the variable capacitance circuit, an equivalent capacitance value of the variable capacitance circuit is caused to change.

### CROSS REFERENCE TO RELATED APPLICATIONS

The present application claims priority and benefit of Chinese Patent Application No. 202311181541.4 filed on Sep. 13, 2023, which is incorporated herein by reference in its entirety.

### TECHNICAL FIELD

Embodiments of the present application relate to the technical field of medical devices, and relate in particular to an isolated resonant power supply circuit, a magnetic resonance imaging system, and an air-cored transformer.

### BACKGROUND

Magnetic resonance (MR) imaging systems are widely used in the field of medical diagnosis. Magnetic resonance systems generally have a main magnet, a gradient amplifier, a radio-frequency amplifier, a gradient coil, a transmit chain module, a transmit/receive coil, a receive chain module, etc. The transmit chain module generates a radio-frequency pulse signal and transmits the radio-frequency pulse signal to the transmit/receive coil. The transmit/receive coil generates a radio-frequency excitation signal to excite a scan subject to generate a magnetic resonance signal. After excitation ends, by means of spatial encoding, the transmit/receive coil acquires the magnetic resonance signal, thereby reconstructing a medical image.

It is presently desirable to dispose the gradient amplifier, the gradient coil assembly, the radio-frequency amplifier, and the radio-frequency coil assembly all in a scan room of the magnetic resonance imaging system. In addition, a power supply also needs to be placed in the scan room to supply power to one or more of the above components in the scan room. A common power supply is based on non-isolated buck topology, and uses a switching transistor as a switch. As long as the switching frequency is sufficiently high, a stable voltage can be output to supply power.

### SUMMARY

Embodiments of the present application provide an isolated resonant power supply circuit, a magnetic resonance imaging system, and an air-cored transformer.

According to an aspect of the embodiments of the present application, an isolated resonant power supply circuit is provided, and is disposed within a scan room of a magnetic resonance imaging system. The isolated resonant power supply circuit comprises: an inverter circuit, a resonant transformer circuit, and a rectifier circuit. The inverter circuit is connected to the resonant transformer circuit and is used for converting inputted direct current power into alternating current power and outputting the same to the resonant transformer circuit. Further, the resonant transformer circuit is used for performing resonant conversion and transformation on the alternating current power, and then outputting the same to the rectifier circuit. Moreover, the rectifier circuit is used for rectifying an alternating current output voltage outputted by the resonant transformer circuit into a direct current voltage for output, so as to supply power. The resonant transformer circuit comprises a variable capacitance circuit and an inductor, and by changing an input voltage of the variable capacitance circuit, an equivalent capacitance value of the variable capacitance circuit is caused to change.

According to an aspect of the embodiments of the present application, a magnetic resonance imaging system is provided, the system comprises a main magnet for generating a main magnetic field; a gradient coil assembly; and a gradient amplifier for exciting the gradient coil assembly to generate a gradient magnetic field on a selected gradient axis so as to apply the gradient magnetic field to the main magnetic field. The system further comprises a radio-frequency coil assembly; a radio-frequency amplifier for exciting the radio-frequency coil assembly to generate a radio-frequency signal; and the isolated resonant power supply circuit according to the preceding aspect. The isolated resonant power supply circuit is disposed within a scan room of the magnetic resonance imaging system, and supplies power to a device in the scan room.

According to an aspect of the embodiments of the present application, an air-cored transformer is provided. The air-cored transformer comprises a bobbin and a first number of windings wound around the bobbin, each winding is formed by winding a wire bundle around the bobbin multiple times, and each wire bundle comprises a second number of winding wires which are twisted together. Further, a third number of winding wires in each winding serve as a primary winding and two ends of the third number of winding wires are connected to a primary circuit of the air-cored transformer. A fourth number of winding wires in each winding serve as a secondary winding, and two ends of the fourth number of winding wires are connected to a secondary circuit of the air-cored transformer, the first number being an integer greater than or equal to 1. Further, the second number, the third number, and the fourth number are all integers greater than 1.

According to an aspect of the embodiments of the present application, a magnetic resonance imaging (MRI) system is provided. The MRI system comprises a main magnet for generating a main magnetic field; a gradient coil assembly; and a gradient amplifier for exciting the gradient coil assembly to generate a gradient magnetic field on a selected gradient axis so as to apply the gradient magnetic field to the main magnetic field. The MRI system further comprises a radio-frequency coil assembly; a radio-frequency amplifier for exciting the radio-frequency coil assembly to generate a radio-frequency signal; and a power supply circuit, disposed within a scan room of the magnetic resonance imaging system, and supplying power to a device in the scan room. The MRI system also includes the air-cored transformer according to the preceding aspect, the air-cored transformer being disposed in the power supply circuit.

Another one of the beneficial effects of the embodiments of the present application is that: by means of the isolated resonant power supply circuit in the embodiments of the present application, a zero-voltage-switching (ZVS) soft switching method can be adopted, so that even in the case of high input voltages, switching loss reduction can still be achieved. In addition, the power supply circuit is enabled to operate at a fixed switching frequency of 1 MHz or more without adjusting the switching frequency, so that noise interference from the power supply circuit to the magnetic resonance imaging system can be avoided, and the output voltage is more stable.

Another one of the beneficial effects of the embodiments of the present application is that: the air-cored transformer in the embodiments of the present application can solves the problem in which conventional magnetic cores cannot operate in a strong magnetic field environment, and can enhance the coupling coefficient between the primary and secondary sides of a transformer.

With reference to the following description and drawings, specific implementations of the embodiments of the present application are disclosed in detail, and the means by which the principles of the embodiments of the present application can be employed are illustrated. It should be understood that the embodiments of the present application are therefore not limited in scope. Within the scope of the spirit and clauses of the appended claims, the embodiments of the present application include many changes, modifications, and equivalents.

### BRIEF DESCRIPTION OF THE DRAWINGS

The included drawings are used to provide further understanding of the embodiments of the present application, which constitute a part of the description and are used to illustrate the implementations of the present application and explain the principles of the present application together with textual description. Evidently, the drawings in the following description are merely some embodiments of the present application, and a person of ordinary skill in the art may obtain other implementations according to the drawings without involving inventive effort. In the drawings:

FIG. 1 is a schematic diagram of a magnetic resonance imaging system according to an embodiment of the present application;

FIG. 2 is a schematic diagram of an isolated resonant power supply circuit according to an embodiment of the present application;

FIG. 3 is a schematic diagram of a resonant transformer circuit 202 according to an embodiment of the present application;

FIG. 4 is a schematic diagram of a voltage feedback circuit according to an embodiment of the present application;

FIG. 5 is a schematic diagram of an air-cored transformer according to an embodiment of the present application;

FIG. 6 is a schematic diagram of a transformer winding configuration according to an embodiment of the present application;

FIG. 7 is a schematic diagram of end terminals of a transformer winding according to an embodiment of the present application;

FIG. 8 is a schematic structural diagram of a transformer after series and parallel connection according to an embodiment of the present application;

FIG. 9 is a schematic diagram of a transformer winding configuration according to an embodiment of the present application;

FIG. 10 is a schematic structural diagram of a transformer after series and parallel connection according to an embodiment of the present application;

FIG. 11 is a schematic diagram of a magnetic resonance imaging system according to an embodiment of the present application.

### DETAILED DESCRIPTION

The foregoing and other features of the embodiments of the present application will become apparent from the following description with reference to the drawings. In the description and drawings, specific implementations of the present application are disclosed in detail, and part of the implementations in which the principles of the embodiments of the present application may be employed are indicated. It should be understood that the present application is not limited to the described implementations. On the contrary, the embodiments of the present application include all modifications, variations, and equivalents which fall within the scope of the appended claims.

In the embodiments of the present application, the terms “first” and “second” and so on are used to distinguish different elements from one another by title, but do not represent the spatial arrangement, temporal order, or the like of the elements, and the elements should not be limited by said terms. The term “and/or” includes any one of and all combinations of one or more associated listed terms. The terms “comprise”, “include”, “have”, etc., refer to the presence of stated features, elements, components, or assemblies, but do not exclude the presence or addition of one or more other features, elements, components, or assemblies.

In the embodiments of the present application, the singular forms “a” and “the” or the like include plural forms, and should be broadly construed as “a type of” or “a class of” rather than being limited to the meaning of “one”. Furthermore, the term “the” should be construed as including both the singular and plural forms, unless otherwise specified in the context. In addition, the term “according to” should be construed as “at least in part according to . . . ”, and the term “based on” should be construed as “at least in part based on . . . ”, unless otherwise clearly specified in the context.

The features described and/or illustrated for one embodiment may be used in one or more other embodiments in an identical or similar manner, combined with features in other embodiments, or replace features in other embodiments. The term “include/comprise” when used herein refers to the presence of features, integrated components, steps, or assemblies, but does not exclude the presence or addition of one or more other features, integrated components, steps, or assemblies.

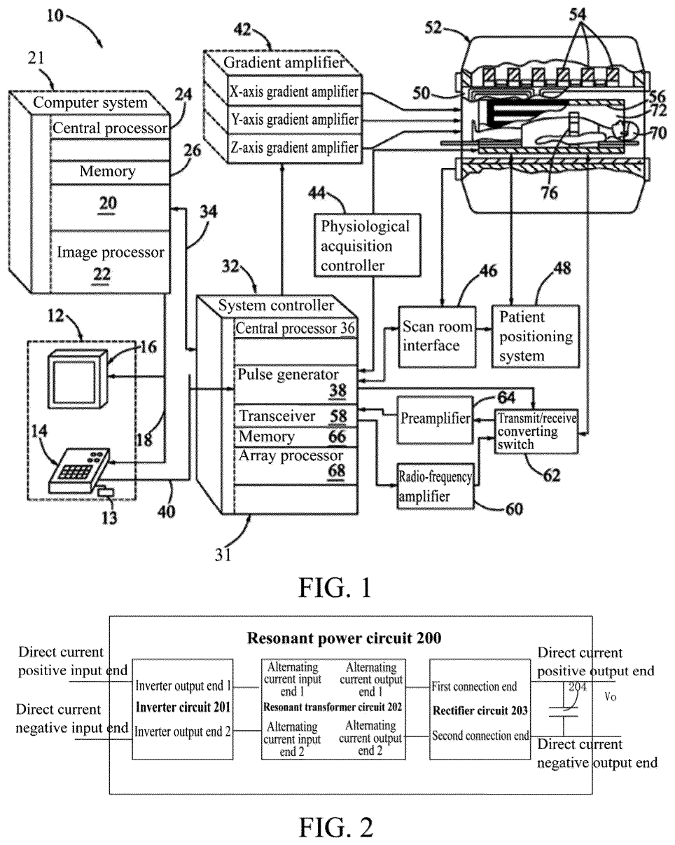

For ease of understanding, FIG. 1 shows a magnetic resonance imaging (MRI) system 10 according to some embodiments of the present invention.

The operation of the magnetic resonance imaging system 10 may be controlled from an operator console 12, the operator console 12 including a keyboard or another input device 13, a control panel 14, and a display 16. The console 12 communicates with a computer system 20 by means of a link 18, and provides an interface to allow an operator to plan a magnetic resonance scan, displays a resulting image, performs image processing on images, and archives data and images. The input device 13 may include a mouse, a joystick, a keyboard, a trackball, a touch screen, an optical wand, a voice control device, or any similar or equivalent input device, and may be used for interactive geometric specifications.

The computer system 20 includes a plurality of modules that communicate with each other by means of, for example, an electrical and/or data connection provided by using a backplane 21. The data connection may be a direct wired link or a wireless communication link, etc. The modules of the computer system 20 include an image processor 22, a central processor 24, and a memory 26. The memory 26 may include a frame buffer for storing image data arrays. In an alternative implementation, the image processor 22 may be replaced with image processing functions running on the central processor 24. The computer system 20 may be linked to an archive media device, a persistent or backup memory storage device, or a network. The computer system 20 may further communicate with a separate system controller 32 by means of a link 34.

In some embodiments, the system controller 32 includes a set of modules that communicate with one another by means of an electrical and/or data connection 31. The data connection 31 may be a wired link, a wireless communication link, or the like. In an alternative implementation, the modules of the computer system 20 and the system controller 32 may be implemented on the same computer system or on a plurality of computer systems. The modules of the system controller 32 include a central processor 36 and a pulse generator 38, the pulse generator 38 being connected to the operator console 12 by means of a communication link 40.

In some embodiments, the pulse generator 38 may be integrated into a scanner device (for example, a resonance assembly 52). A system-controlled computer receives, by means of the link 40, a command from the operator indicating that a scanning sequence is to be implemented. By means of sending an instruction, command, and/or request describing the timing, strength, and shape of a radio-frequency pulse and pulse sequence to be generated as well as the timing and length of a data acquisition window, the pulse generator 38 operates a system component that emits (i.e., implements) a desired pulse sequence. The pulse generator 38 is connected to a gradient amplifier 42 and generates data referred to as gradient waveforms, and the gradient waveforms control the timing and shape of gradient pulses to be used during a scan.

In some embodiments, the pulse generator 38 may further receive data of a patient from a physiological acquisition controller 44. The physiological acquisition controller 44 receives signals from a plurality of different sensors connected to the patient, such as electrocardiogram signals from electrodes attached to the patient. The pulse generator 38 is connected to a scan room interface 46. The scan room interface 46 receives, from various sensors, signals associated with the conditions of the patient and a magnet system. A patient positioning system 48 receives, also by means of the scan room interface 46, a command to move a patient table to a desired location for scanning.

In some embodiments, the gradient waveforms generated by the pulse generator 38 are applied to the gradient amplifier 42. The gradient amplifier 42 includes an X-axis gradient amplifier, a Y-axis gradient amplifier, and a Z-axis gradient amplifier. Each gradient amplifier excites a corresponding physical gradient coil in a gradient coil assembly 50, and generates a magnetic field gradient pulse used for spatially encoding the acquired signal. The gradient coil assembly 50 forms a part of the resonance assembly 52, and the resonance assembly 52 includes a polarized superconducting magnet having a superconducting main coil 54. The resonance assembly 52 may include a whole-body radio-frequency coil 56, a surface or parallel imaging coil 76, or both. The coils 56 and 76 of the radio-frequency coil assembly may be configured for transmission and reception, or transmission only, or reception only. A patient or imaged subject 70 may be placed within a cylindrical patient imaging volume 72 of the resonance assembly 52. A transceiver 58 in the system controller 32 generates pulses that are amplified by a radio-frequency amplifier 60 and coupled to the radio-frequency coils 56 and 76 by means of a transmit/receive switch 62. The resulting signals emitted by excited nuclei in the patient may be sensed by the same radio-frequency coil 56 and coupled to a preamplifier 64 by means of the transmit/receive switch 62. Alternatively, the signals emitted by the excited nuclei may be sensed by a separate receive coil, such as the parallel or surface coil 76. Amplified magnetic resonance signals are demodulated, filtered, and digitized in a receiver portion of the transceiver 58. The transmit/receive switch 62 is controlled by signals from the pulse generator 38 so as to electrically connect the radio-frequency amplifier 60 to the radio-frequency coil 56 during a transmit mode, and to connect the preamplifier 64 to the radio-frequency coil 56 during a receive mode. The transmit/receive switch 62 may further enable the use of a separate radio-frequency coil (e.g., the parallel or surface coil 76) in the transmit or receive mode.

The magnetic resonance signals sensed by the radio-frequency coil 56 or the parallel or surface coil 76 are digitized by the transceiver 58, and are transferred to a memory 66 in the system-controlled computer. Generally, data frames corresponding to the magnetic resonance signals are temporarily stored in the memory 66 until they are subsequently transformed to create images. An array processor 68 uses known transform methods (most commonly Fourier transform) to create images from the magnetic resonance signals. These images are transferred, by means of the link 34, to the computer system 20, and the images are stored in the memory in the computer system 20. In response to a command received from the operator console 12, said image data may be archived in a long-term storage device, or may be further processed by means of the image processor 22, transferred to the operator console 12, and presented on the display 16.

Unlike power supplies in other fields, power supplies operating in a scan room of a magnetic resonance imaging system cannot contain any magnetic components. In addition, the switching frequency of the power supplies must be fixed at 1 MHz or more in order to prevent switching noise from affecting a magnetic resonance imaging (for example, a 1.5 T magnetic resonance imaging system) scan. The operating frequency of the currently used power supply based on buck topology is 1.4 MHZ, and energy consumption of one switching period is approximately ½CₛV². To limit the switching loss (mainly caused by charging and discharging of a parasitic capacitor Cₛ), the input voltage V of the power supply needs to be small. If the input voltage increases, the switching loss increases dramatically. If the switching frequency is further increased to satisfy higher requirements of a magnetic resonance imaging system (for example, a 3T magnetic resonance imaging system), the switching loss increases linearly as the frequency increases, so that the power supply circuit is inflexible and cannot be applied in scenarios of high input voltages and high switching frequencies. In addition, commonly used power supply circuits, due to transformers therein using ferromagnetic substances, are not suitable for operating in the strong magnetic field environment of the magnetic resonance imaging system.

In view of at least one of the above problems, the embodiments of the present application provide an isolated resonant power supply circuit, a magnetic resonance imaging system, and a transformer, which are described below with reference to the embodiments.

The embodiments of the present application provide an isolated resonant power supply circuit, disposed within a scan room of a magnetic resonance imaging system, and used for supplying power to one or more devices in the scan room of the magnetic resonance imaging system. For example, the isolated resonant power supply circuit may be used for supplying power to any one of a gradient amplifier and a radio-frequency amplifier in the scan room. By disposing the isolated resonant power supply circuit within the scan room, cables, filters and the like can be reduced, thereby reducing costs of the magnetic resonance imaging system.

FIG. 2 is a schematic diagram of an isolated resonant power supply circuit according to an embodiment of the present application. As shown in FIG. 2, the isolated resonant power supply circuit 200 includes: an inverter circuit 201, a resonant transformer circuit 202, and a rectifier circuit 203.

The inverter circuit 201 is connected to the resonant transformer circuit 202, and used for converting inputted direct current power into alternating current power and outputting the same to the resonant transformer circuit 202.

The resonant transformer circuit 202 is used for performing resonant conversion and transformation on the alternating current power, and then outputting the same to the rectifier circuit 203.

The rectifier circuit 203 is used for rectifying an alternating current output voltage outputted by the resonant transformer circuit 202 into a direct current voltage for output, so as to supply power.

In some embodiments, the inverter circuit 201 may convert direct current power into alternating current power (such as a high-frequency square wave). The inverter circuit 201 includes a direct current positive input end, a direct current negative input end, an inverter output end 1, and an inverter output end 2. The direct current positive input end and the direct current negative input end are used for the input of the direct current power. The inverter circuit 201 may be a full-bridge inverter circuit (such as including four power switching transistors), or a half-bridge inverter circuit (such as including two power switching transistors), and the embodiments of the present application are not limited thereto. In addition, the above switching transistors are various power semiconductor switch devices including power metal oxide semi-conductor field effect transistors (MOSFETs), insulated gate bipolar transistors (IGBTs), BJTs, thyristors, IGCTs, etc. The above devices in the inverter circuit 201 and the connection relationships thereof are merely illustrative. Reference may be made to the related art for details, and the present application is not limited thereto.

In some embodiments, the inverter output end 1 and the inverter output end 2 of the inverter circuit 201 are connected to an alternating current input end 1 and an alternating current input end 2 of the resonant transformer circuit 202. The alternating current power (the high-frequency square wave) outputted by the inverter circuit 201 is applied to the alternating current input end 1 and the alternating current input end 2 of the resonant transformer circuit 202, and generates high-frequency resonance, thereby eliminating harmonics of the square wave, and outputting a sinusoidal wave of a fundamental frequency. The sinusoidal wave is transmitted by means of the transformer from a primary side to a secondary side, and after the voltage is boosted or bucked according to application requirements, connection with the rectifier circuit 203 is established by means of an alternating current output end 1 and an alternating current output end 2, so that the transformed sinusoidal wave is outputted to the rectifier circuit 203.

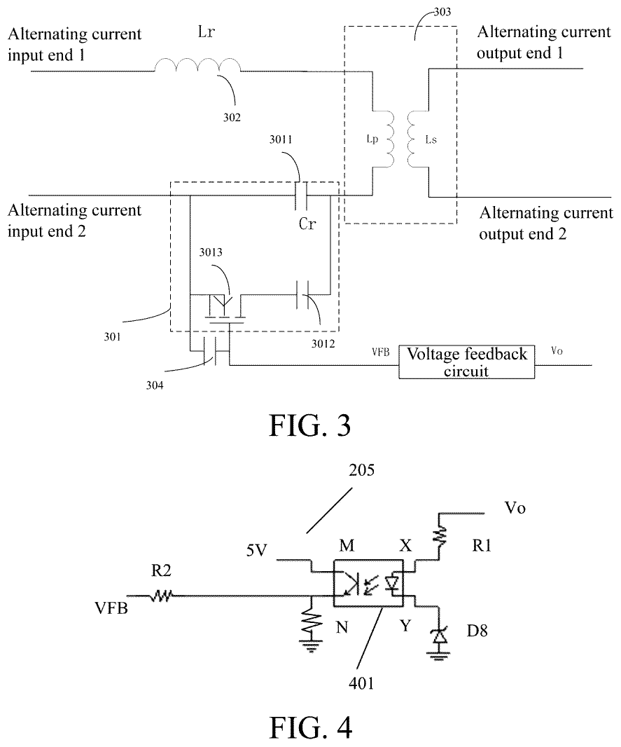

FIG. 3 is a schematic diagram of a resonant transformer circuit 202 according to an embodiment of the present application. As shown in FIG. 3, the resonant transformer circuit 202 includes a variable capacitance circuit 301, an inductor 302, and an air-cored transformer 303. By changing an input voltage of the variable capacitance circuit 301, an equivalent capacitance value of the variable capacitance circuit 301 is caused to change. The variable capacitance circuit 301 includes a first capacitor 3011, a second capacitor 3012, and a variable resistor 3013. One end of the second capacitor 3012 is connected to one end of the variable resistor 3013. The other end of the second capacitor 3012 is connected to one end of the first capacitor 3011. The other end of the first capacitor 3011 is connected to the other end of the variable resistor 3013. The two ends of the first capacitor 3011 may also be regarded as two terminals of the variable capacitance circuit. An equivalent circuit model of the air-cored transformer 303 includes an inherent lumped circuit parasitic element including a primary inductor Lp, where the primary inductor Lp is not a component that really exists. FIG. 3 is merely for illustrating the effect of the presence of the primary inductor.

In some embodiments, the variable capacitance circuit 301, the inductor 302, and the primary inductor (i.e., excitation inductor) Lp are connected in series, but the present application does not limit the order of connection of the inductor 302, the primary inductor, and the variable capacitance circuit 301. For example, as shown in FIG. 3, the primary inductor is located between the variable capacitance circuit 301 and the inductor 302. That is, one terminal of the variable capacitance circuit 301 and one end of the inductor 302 serve as the alternating current input end 1 and the alternating current input end 2 of the resonant transformer circuit 202, and are respectively connected to the inverter output end 1 and the inverter output end 2 of the inverter circuit 201. Alternatively, not shown in the drawing, the inductor 302 may be located between the variable capacitance circuit 301 and the primary inductor Lp. That is, one terminal of the variable capacitance circuit 301 and one end of the primary inductor Lp serve as the alternating current input end 1 and the alternating current input end 2 of the resonant transformer circuit 202, and are respectively connected to the inverter output end 1 and the inverter output end 2 of the inverter circuit 201. No further examples will be provided herein.

In some embodiments, the rectifier circuit 203 may convert the sinusoidal wave into stable direct current voltages for output, and may be a full-bridge rectifier circuit or a half-bridge rectifier circuit. The rectifier circuit 203 includes a first connection end, a second connection end, a direct current positive output end, and a direct current negative output end. The direct current positive output end and the direct current negative output end are used for outputting the direct current power, and the first connection end and the second connection end may be respectively connected to the alternating current output end 1 and the alternating current output end 2 of the resonant transformer circuit 202. The rectifier circuit 203 includes rectifier tubes. The rectifier tubes include at least one diode and/or at least one synchronous rectifier tube, that is, the rectifier tubes can all be diodes, or the rectifier tubes can all be synchronous rectifier tubes, or the rectifier tubes can be a combination of diodes and synchronous rectifier tubes. The above devices in the inverter circuit 203 and the connection relationships thereof are merely illustrative. Reference may be made to the related art for details, and the present application is not limited thereto.

In some embodiments, the isolated resonant power supply circuit 200 may further include an output capacitor 204. Two ends of the output capacitor 204 are respectively connected to the direct current positive output end and the direct current negative output end of the rectifier circuit 203, i.e., connected in parallel to the output ends of the rectifier circuit 203.

The inventors have found that in existing resonant circuits, the switching frequency can be adjusted to be away from or close to a resonance point, so as to adjust the magnitude of power flowing from the primary side to the secondary side. However, in magnetic resonance imaging systems, in order to prevent switching noise from affecting magnetic resonance imaging scans (such as the receiving frequency of the receiver), the switching frequency of the power supply cannot be arbitrarily changed; hence, a variable capacitance circuit can be designed to adjust a resonance capacitance value, thereby adjusting the magnitude of power flowing from the primary side to the secondary side.

The working principle of the variable capacitance circuit will be described below.

In some embodiments, by changing an input voltage of the variable resistor to change the input voltage of the variable capacitance circuit, the equivalent capacitance value of the variable capacitance circuit can be changed. That is, the input voltage of the variable resistor is changed to change the equivalent resistance value of the variable resistor, such that the equivalent capacitance value of the variable capacitance circuit is caused to change. The equivalent capacitance value of the variable capacitance circuit is changed between a first value and a second value. The first value is the capacitance value of the first capacitor, and the second value is the sum of the capacitance values of the first capacitor and the second capacitor.

In some embodiments, the variable resistor is a switching transistor operating in a linear region. By changing the input voltage of the variable resistor to change the degree of linear conduction of the switching transistor, the equivalent capacitance value of the variable capacitance circuit is caused to change. The switching transistor may be a MOS transistor, but the embodiments of the present application is not limited thereto. One end and the other end of the variable resistor 3013 respectively serve as a source end and a drain end of the switching transistor. The switching transistor operating in a linear region means that the switching transistor operates in a resistive state. The degree of linear conduction of the switching transistor being different means that an equivalent resistance value corresponding to the switching transistor (between the source and the drain) is different. When the switching transistor is fully turned on, the switching transistor can be regarded as a short circuit (one wire), and the resistance value is regarded as 0. The variable capacitance circuit can be regarded as a parallel circuit of the first capacitor and the second capacitor, and the equivalent capacitance value thereof is the second value. When the switching transistor is fully turned off, the switching transistor can be regarded as an open circuit, that is, the resistance value is regarded as infinite. The variable capacitance circuit can be regarded as only including the first capacitor, that is, the equivalent capacitance value of the variable capacitance circuit is the first value. If the switching transistor is between fully on and fully off, the resistance value thereof is related to the degree of conduction thereof. The equivalent capacitance value of the variable capacitance circuit is changed between the first value and the second value, and the change is monotonic. That is, the greater the degree of conduction, the closer the equivalent capacitance value of the variable capacitance circuit is to the second value, and the smaller the degree of conduction, the closer the equivalent capacitance value of the variable capacitance circuit is to the first value.

In some embodiments, the equivalent capacitance value of the variable capacitance circuit may be changed according to load-based dynamic changes in the feedback voltage of the resonant power supply circuit, as shown in FIG. 3 (not shown in FIG. 2). The isolated resonant power supply circuit further includes: a voltage feedback circuit 205, respectively connected to the variable capacitance circuit and the rectifier circuit, and used for feeding the direct current voltage outputted by the rectifier circuit back to the variable capacitance circuit. In addition, the feedback voltage VFB of the voltage feedback circuit 205 is used as the input voltage of the variable resistor.

FIG. 4 is a schematic structural diagram of a voltage feedback circuit 205 according to the present application. As shown in FIG. 4, the voltage feedback circuit 205 includes an optically coupled isolator 401. A terminal X of the optically coupled isolator 401 is used for inputting (optionally, via a resistor R1) a direct current voltage Vo outputted by the rectifier circuit. A terminal Y of the optically coupled isolator 401 is used for grounding (optionally, via a diode D8). A terminal M of the optically coupled isolator 401 is used for inputting a supply voltage (e.g., 5 V, 8 V, 10 V or the like). A terminal N of the optically coupled isolator 401 is connected to the variable capacitance circuit (optionally, via a resistor R2), and outputs the feedback voltage VFB. Parameters of the optically coupled isolator 401 and the values of R1 and R2 may be designed according to requirements, and the embodiments of the present application are not limited thereto.

In some embodiments, when the variable resistor is the aforementioned switching transistor, the voltage feedback circuit is connected to a gate of the switching transistor. For example, the terminal N of the optically coupled isolator 401 is connected to the gate of the switching transistor (optionally, via the resistor R2). The feedback voltage serves as the input voltage of the variable resistor, and controls the equivalent resistance value of the variable resistor. That is, the magnitude of channel resistance of the switching transistor is controlled by using a gate voltage of the switching transistor. In other words, the magnitude of channel resistance of the switching transistor is caused to change by changing the feedback voltage (that is, when the feedback voltage changes, the channel resistance of the switching transistor changes accordingly), so that the equivalent capacitance value of the variable capacitance circuit is changed between the first value and the second value.

In some embodiments, when the feedback voltage controls the switching transistor to fully turn on, that is, when the feedback voltage increases such that the gate voltage of the switching transistor increases to be greater than or equal to a turn-on voltage V1 of the switching transistor and the switching transistor is fully turned on, the switching transistor can be regarded as a short circuit (one wire), and the resistance value is regarded as 0. The variable capacitance circuit can be regarded as a parallel circuit of the first capacitor and the second capacitor, and the equivalent capacitance value thereof is the second value. When the feedback voltage controls the switching transistor to fully turn off, that is, when the feedback voltage decreases such that the gate voltage of the switching transistor decreases to be less than or equal to a turn-off voltage V2 of the switching transistor and the switching transistor is turned off, the switching transistor can be regarded as an open circuit, that is, the resistance value is regarded as infinite. The variable capacitance circuit can be regarded as only including the first capacitor, that is, the equivalent capacitance value of the variable capacitance circuit is the first value. When the feedback voltage changes between V1 and V2, the degree of conduction of the switching transistor is caused to change, such that the equivalent capacitance value of the variable capacitance circuit is changed between the first value and the second value. The values of V1 and V2 are related to the switching transistor, and the embodiments of the present application are not limited thereto.

In some embodiments, the magnitude of the feedback voltage is affected by the load. That is, a change in the load causes the output voltage to change, and the feedback voltage is therefore changed, so that the equivalent resistance of the variable resistor is caused to change, thereby changing the equivalent capacitance value of the variable capacitance circuit. In another aspect, a change in the equivalent capacitance value of the variable capacitance circuit causes a corresponding change in the power flowing from the primary side to the secondary side, and said change in the power can further compensate for the impact of the load change on the output voltage, thereby stabilizing the output voltage. The detailed description is provided below.

For example, when the load is light, which is equivalent to an increase in the load resistance, the output voltage is caused to increase, the feedback voltage increases, the degree of conduction of the switching transistor increases, the on-resistance of the switching transistor decreases, and the equivalent capacitance of the variable capacitance circuit increases, so that the resonant frequency decreases (away from the maximum resonant frequency), and the power flowing from the primary side to the secondary side decreases, thereby reducing the output voltage, that is, avoiding the problem of output voltage rise caused by a light load, and stabilizing the output voltage.

For example, when the load is heavy (for example, when the load changes from no load to full load), which is equivalent to a decrease in load resistance, the output voltage will drop (hereinafter, simply referred to as a voltage drop), the feedback voltage VFB also decreases, the degree of conduction of the switching transistor decreases, the on-resistance of the switching transistor increases, and the equivalent capacitance of the variable capacitance circuit decreases, so that the resonant frequency increases (approaching the maximum resonant frequency), and the power flowing from the primary side to the secondary side increases, thereby increasing the output voltage, that is, avoiding the problem of output voltage drop caused by a heavy load, and stabilizing the output voltage.

As can be seen from the above embodiments, existing common switching transistors are all hard switches. The drain to source voltages and currents of the switching transistor may overlap when the switching transistor is turned on and off, and the region in which the voltages and currents overlap represents the turn-on losses and turn-off losses of the switching transistor. In particular, when the input voltage of the power supply circuit is increased, the switching losses increase dramatically. In the embodiments of the present application, by means of the isolated resonant power supply circuit, a ZVS soft switching method can be adopted, so that even in the case of high input voltages, switching loss reduction can still be achieved. In addition, the power supply circuit is enabled to operate at a fixed switching frequency of 1 MHz or more without adjusting the switching frequency, so that noise interference from the power supply circuit to the magnetic resonance imaging system can be avoided, and the output voltage is more stable.

In the above example, the variable resistor is exemplified as a switching transistor operating in a linear region, but the embodiments of the present application are not limited thereto. The variable resistor may also be a digital variable resistor, and a correspondence relationship between feedback voltages and resistance values of the digital variable resistor may be set in advance, and the resistance value of the digital variable resistor may be adjusted according to the value of the feedback voltage and the correspondence relationship, so as to change the equivalent capacitance value of the variable capacitance circuit, which is not repeatedly described herein. Other implementations of the variable resistor may also be adopted, and the present application is not limited thereto.

How to design the capacitance values of the first capacitor and the second capacitor is described below.

In some embodiments, an inductance value Lr (resonant inductance) of the inductor may be predetermined according to circuit requirements. The first value and the second value are determined according to said resonant inductance and output powers under different load conditions. For example, in the case of a light load, the value of the first capacitor, i.e., the first value, is determined according to the resonant inductance and the output power, and in the case of a heavy load or a full load, the value of the second capacitor, i.e., the second value, is determined according to the resonant inductance, the output power, and the first value, and the specifics can be acquired by means of simulation by referring to the related art. The first value and the second value may be values greatly different from each other, so that the equivalent capacitance of the variable capacitance circuit can have a greater adjustable range. For example, the first value is 1 nF, and the second value is 100 nF. This is merely an example, and the embodiments of the present application are not limited thereto.

In some embodiments, as shown FIG. 3, the resonant transformer circuit further includes a third capacitor 304. One end of the third capacitor is connected to the other end of the first capacitor, and the other end of the third capacitor is connected to the gate of the switching transistor. The channel resistance value of the switching transistor is relatively sensitive to changes in the feedback voltage. For example, if the feedback voltage increases by a small amount, the channel resistance value will decrease by a large amount. Hence, the feedback tends to cause the problem of oscillation. The third capacitor is added to the resonant transformer circuit to reduce the speed of changes in the channel resistance value of the switching transistor, so that the sensitivity of the channel resistance value of the switching transistor to changes can be reduced. The capacitance value of the third capacitor may be determined according to requirements, and may be set to, for example, 100 nF, but the embodiments of the present application are not limited thereto.

In some embodiments, the air-cored transformer 303 is applicable to any air-cored transformer structure. However, in the absence of a magnetic core, if a primary winding and a secondary winding are placed apart, then the coupling between the windings is poor, resulting in reduced coupling coefficients, high noise, and low efficiency. Therefore, in order to further increase the coupling coefficient between the primary winding and the secondary winding, the embodiments of the present application further provide an air-cored transformer, the air-cored transformer including a bobbin and a first number of windings wound around the bobbin. Each winding is formed by winding a wire bundle around the bobbin multiple times, and each wire bundle includes a second number of winding wires which are twisted together. The first number is an integer greater than or equal to 1, and the second number is an integer greater than 1. For example, the second number is greater than or equal to a second threshold that may be determined according to requirements. The winding wire may be an enameled wire, for example, an insulated copper wire. The second number of winding wires are twisted together to form a wire bundle, and the wire bundle is closely wound around the bobbin multiple times to form a winding. Each winding is formed in the same manner, which will not be described in detail herein.

In some embodiments, a third number of winding wires in each winding serve as a primary winding, and two ends of the third number of winding wires are connected to a primary circuit of the air-cored transformer. A fourth number of winding wires in each winding serve as a secondary winding, and two ends of the fourth number of winding wires are connected to a secondary circuit of the air-cored transformer. The third number and the fourth number are both integers greater than 1. The third number of winding wires and the fourth number of winding wires may be randomly selected, and the present application is not limited thereto. For example, the third number may be equal to the fourth number, and may be equal to half of the second number, but the present application is not limited thereto. That is, the second number of winding wires in one wire bundle are divided into primary winding wires and secondary winding wires. For example, 40 winding wires are twisted together to form one wire bundle, and the wire bundle is wound around the bobbin one turn after another. 20 winding wires are randomly selected from one end of the wire bundle (winding wires) as primary winding wires, and the respective other ends of the 20 winding wires are determined. The respective ends and the respective other ends of the 20 winding wires are connected to the primary circuit of the air-cored transformer. The remaining 20 winding wires serve as secondary winding wires, and the two ends of the remaining 20 winding wires are connected to the secondary circuit of the air-cored transformer.

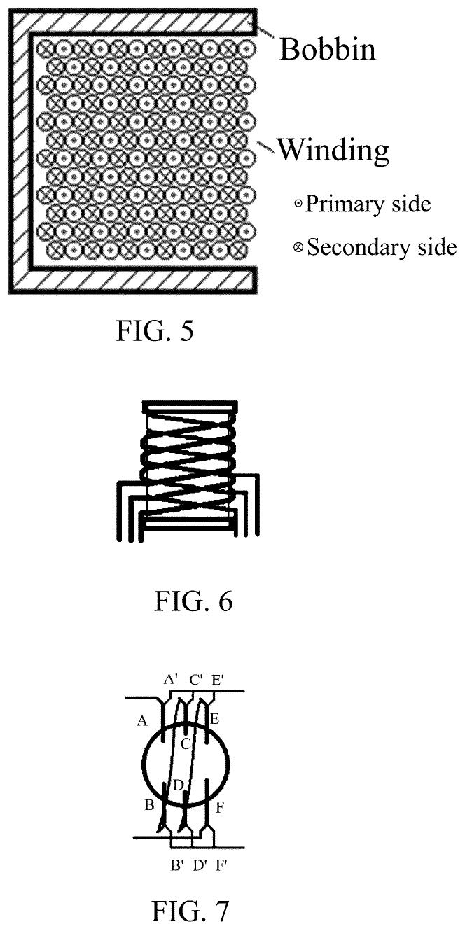

FIG. 5 a schematic cross-sectional view of a winding according to an embodiment of the present application. As shown in FIG. 5, although the primary winding wires and the secondary winding wires are randomly selected, since the primary winding wires and the secondary winding wires in one winding are mixed and twisted together, it can be ensured that the primary winding wires and the secondary winding wires are uniformly distributed in said winding. Since each winding wire in the primary winding is surrounded by a plurality of secondary winding wires, magnetic flux generated by the primary winding can be coupled to the secondary winding to a greater extent, and similarly, magnetic flux generated by the secondary winding can be coupled to the primary winding to a greater extent, thereby improving the coupling coefficient between the primary and secondary sides.

In some embodiments, a transformer operating at a high frequency (e.g., greater than 1 MHZ) may have a skin effect, and in order to mitigate the skin effect and reduce losses, the diameter of each winding wire is less than or equal to a first threshold that may be set to a relatively small value as needed. For example, the diameter of each winding wire may be 0.1 mm, but the embodiments of the present application are not limited thereto.

In some embodiments, in order to acquire the optimal coupling coefficient, the number of turns (the number of turns of the winding) of the primary side is the same as that of the secondary side. That is, the primary-to-secondary turn ratio of the transformer is 1:1. In this case, when the input voltage is 48 V and the output voltage is 15 V, the duty cycle is (15×2)/48=0.625. However, when the output voltage is 5 V, the duty cycle is (5×2)/48=0.208. That is, in the case of low output voltages, if the primary-to-secondary turn ratio is still 1:1, the duty cycle will be low, thereby limiting the primary-secondary power conversion efficiency. Therefore, in the case of low output voltages, the primary-to-secondary turn ratio of the transformer may be set to be greater than 1 for a large change ratio, so as to achieve a greater switching duty cycle, thereby improving efficiency. The following describes how the primary-to-secondary turn ratio of the transformer is set to be greater than 1 in the embodiments of the present application.

In some embodiments, the first number may be set to an integer greater than 1. That is, the transformer has a plurality of (the first number of) windings, that is, the transformer is formed by winding a plurality of (the first number of) wire bundles around the bobbin. The transformer has the first number of windings, which means that the transformer has the first number of primary windings and the first number of secondary windings since each winding includes a primary winding and a secondary winding. The plurality of (the first number of) primary windings in the first number of windings can be connected in series, and the plurality of (the first number of) secondary windings in the first number of windings can be connected in parallel, so that the primary-to-secondary turn ratio is changed to the first number: 1. That is, the turn ratio is greater than 1 to achieve a greater switching duty cycle.

In some embodiments, connecting the first number of primary windings in series includes: each primary winding includes the third number (hereinafter referred to as a group) of winding wires having two ends. Differently named ends of different groups of winding wires (different primary windings) are connected together to connect the first number of primary windings in series, and the remaining two ends that are not connected together are connected to the primary circuit of the air-cored transformer, for example, connected to the inductor and the variable capacitance circuit, respectively.

In some embodiments, connecting the first number of secondary windings in parallel includes: each secondary winding includes the fourth number (hereinafter referred to as a group) of winding wires having two ends. Identically named ends of different groups of winding wires (different secondary windings) are connected together to connect the first number of secondary windings in parallel, and the two ends connected in parallel are connected to the secondary circuit of the air-cored transformer, for example, connected to the first connection end and the second connection end of the rectifier circuit, respectively.

In some embodiments, voltages of different secondary windings may not be exactly the same, and if a plurality of secondary windings are directly connected in parallel, a ring current will be generated. In order to prevent a ring current from being generated between the secondary windings, all secondary windings in the first number of windings can be connected in parallel after being rectified by a rectifier. The number of rectifiers is also the first number, and the first number of rectifiers are in one-to-one correspondence with the first number of secondary windings. That is, the two ends of each group of winding wires are first connected to the rectifier corresponding thereto, and then the identically named ends among the respective two output ends of the rectifiers are connected together to achieve parallel connection.

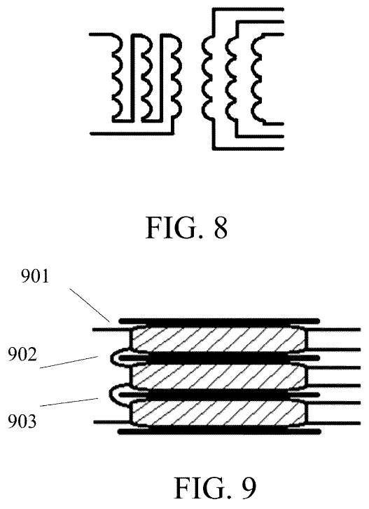

In some embodiments, the first number of windings are all wound in a slot of the bobbin. Using three as the first number for example, FIG. 6 is a schematic diagram of the first number of windings according to an embodiment of the present application, and FIG. 7 is a schematic diagram of end terminals of the first number of windings according to an embodiment of the present application. As shown in FIG. 6 and FIG. 7, the bobbin is provided with a slot, and the three windings (wire bundles) are all wound in the slot. The two ends of the third number of primary winding wires in the first wire bundle are ends A and ends B. The two ends of the third number of primary winding wires in the second wire bundle are ends C and ends D. The two ends of the third number of primary winding wires in the third wire bundle are ends E and ends F. The differently named ends B and C of the third number of primary winding wires in the first wire bundle and of the third number of primary winding wires in the second wire bundle are connected together, and the differently named ends D and E of the third number of primary winding wires in the second wire bundle and of the third number of primary winding wires in the third wire bundle are connected together, thereby connecting the three primary windings in series. The remaining ends A and F of the third number of primary winding wires are connected to the primary circuit (for example, the inductor and the variable capacitance circuit). The two ends of the fourth number of secondary winding wires in the first wire bundle are ends A′ and ends B′. The two ends of the fourth number of secondary winding wires in the second wire bundle are ends C′ and ends D′. The two ends of the fourth number of secondary winding wires in the third wire bundle are ends E′ and ends F′. The identically named ends B′, D′, and F′ of the fourth number of secondary winding wires in the first wire bundle, the fourth number of secondary winding wires in the second wire bundle, and the fourth number of secondary winding wires in the third wire bundle are connected together, and the identically named ends A′, C′, and E′ of the fourth number of secondary winding wires in the first wire bundle, the fourth number of secondary winding wires in the second wire bundle, and the fourth number of secondary winding wires in the third wire bundle are connected together, thereby connecting the three secondary windings in parallel. The ends A′ and B′ are connected to the secondary circuit (for example, the rectifier circuit). FIG. 8 is a schematic structural diagram of a transformer after series and parallel connection according to an embodiment of the present application. As shown in FIG. 8, three primary windings are connected in series, and three secondary windings are connected in parallel.

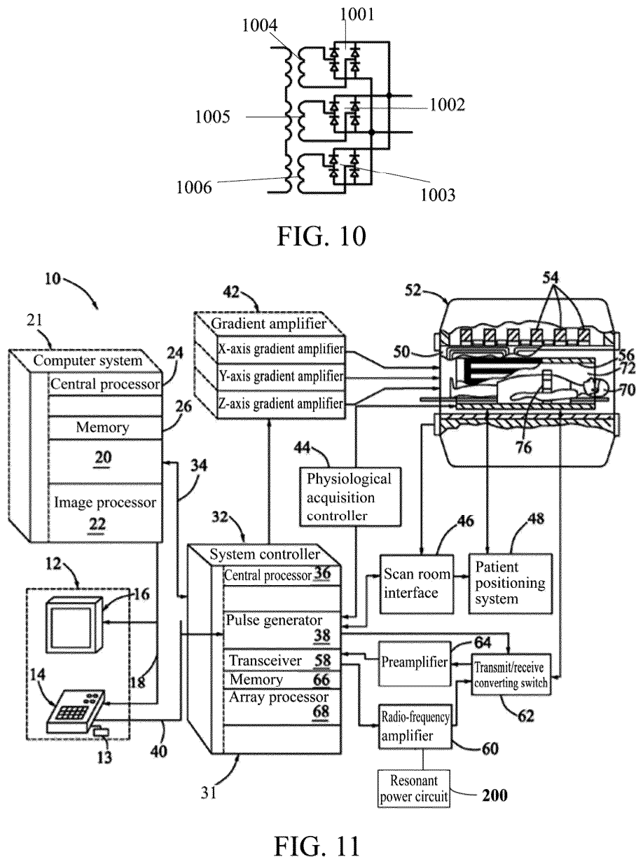

In some embodiments, the first number of windings are respectively wound in the first number of slots of the bobbin. Using three as the first number for example, FIG. 9 is a schematic diagram of the first number of windings according to an embodiment of the present application. As shown in FIG. 9, the bobbin is provided with the first number (three) of slots 901, 902, 903. Each wire bundle in the three windings (wire bundles) is respectively wound in the slot. Differently named ends of one group of primary winding wires wound in adjacent slots are connected to each other, and identically named ends of one group of secondary winding wires wound in adjacent slots are connected to each other. In order to limit the generation of a ring current, the identically named ends may be connected in parallel after the secondary winding in each slot is rectified by the rectifier, and the winding in each slot may be a helically wound wire bundle, but the embodiments of the present application are not limited thereto. FIG. 10 is a schematic structural diagram of a transformer after series and parallel connection according to an embodiment of the present application. As shown in FIG. 10, three primary windings are connected in series, and three secondary windings 1004, 1005, 1006 respectively pass through rectifiers 1001, 1002, 1003, and are then connected in parallel.

In addition, the series and parallel connection method in FIG. 10 results in a smaller magnetic length compared with the series and parallel connection method in FIG. 8, so that magnetic leakage flux of the transformer is smaller.

In the above example, the turn ratio of the transformer is changed to 3:1. When the input voltage is 48 V and the output voltage is 5 V, the switching duty cycle is (2×5×3)/48=0.625, thereby achieving a greater switching duty cycle.

In the isolated resonant power supply circuit according to the embodiments of the present application, by changing the input voltage of the variable resistor, the equivalent capacitance value of the variable capacitance circuit is caused to change, so that the ZVS soft switching method can be adopted, and even in the case of high input voltages, switching loss reduction can still be achieved. In addition, since the capacitance value is variable, the power supply circuit is enabled to operate at a fixed switching frequency of 1 MHz or more without adjusting the switching frequency, so that noise interference from the power supply circuit to the magnetic resonance imaging system can be avoided, and the output voltage is more stable.

In the air-cored transformer according to the embodiments of the present application, a plurality of winding wires are twisted to form a wire bundle, and then the wire bundle is wound around a bobbin multiple times to form a transformer winding, so that the problem in which conventional magnetic cores cannot operate in a strong magnetic field environment can be solved, and the coupling coefficient between the primary and secondary sides of the transformer can be enhanced.

The embodiments of the present application further provide a magnetic resonance imaging system. The configuration of the magnetic resonance imaging system is as shown in FIG. 11, and features identical to those of FIG. 1 are not repeated herein.

In some embodiments, the magnetic resonance imaging system differs from the foregoing magnetic resonance imaging system in FIG. 1 in that: this magnetic resonance imaging system further includes the isolated resonant power supply circuit 200 of the foregoing embodiments, which is disposed within the scan room of the magnetic resonance imaging system, and is used for supplying power to one or more devices in the scan room of the magnetic resonance imaging system. For example, the isolated resonant power supply circuit may be used for supplying power to any one of a gradient amplifier and a radio-frequency amplifier in the scan room.

The embodiments of the present application may further provide an air-cored transformer. The air-cored transformer includes a bobbin and a first number of windings wound around the bobbin. Each winding is formed by winding a wire bundle around the bobbin multiple times, and each wire bundle includes a second number of winding wires which are twisted together. A third number of winding wires in each winding serve as a primary winding, two ends of the third number of winding wires are connected to a primary circuit of the air-cored transformer, a fourth number of winding wires in each winding serve as a secondary winding, and two ends of the fourth number of winding wires are connected to a secondary circuit of the air-cored transformer, the first number being an integer greater than or equal to 1, and the second number, the third number, and the fourth number all being integers greater than 1. Implementations of the air-cored transformer are as described above, and will not be described again herein. The air-cored transformer may be applied to a power supply circuit. The power supply circuit is not limited the foregoing isolated resonant power supply circuit, and may be a power supply circuit having another structure, and the embodiments of the present application are not limited thereto.

The embodiments of the present application further provide a magnetic resonance imaging system. The configuration of the magnetic resonance imaging system is as shown in FIG. 1, and features identical to those of FIG. 1 are not repeated herein.

In some embodiments, the magnetic resonance imaging system differs from the foregoing magnetic resonance imaging system in FIG. 1 in that: this magnetic resonance imaging system further includes the air-cored transformer of the foregoing embodiments, which is disposed within the scan room of the magnetic resonance imaging system, and applied to a power supply circuit for supplying power to a device in the scan room of the magnetic resonance imaging system.

The above apparatus and method of the present application can be implemented by hardware, or can be implemented by hardware in combination with software. The present application relates to the foregoing type of computer-readable program. When executed by a logic component, the program causes the logic component to implement the foregoing apparatus or a constituent component, or causes the logic component to implement various methods or steps as described above. The present application further relates to a storage medium for storing the above program, such as a hard disk, a magnetic disk, an optical disk, a DVD, a flash memory, etc.

The method/apparatus described with reference to the embodiments of the present application may be directly embodied as hardware, a software module executed by a processor, or a combination of the two. For example, one or more of the functional block diagrams and/or one or more combinations of the functional block diagrams as shown in the drawings may correspond to either software modules or hardware modules of a computer program flow. The foregoing software modules may respectively correspond to the steps shown in the figures. The foregoing hardware modules may be implemented, for example, by firming the foregoing software modules by using a field-programmable gate array (FPGA).

The software modules may be located in a RAM memory, a flash memory, a ROM memory, an EPROM memory, an EEPROM memory, a register, a hard disk, a removable disk, a CD-ROM, or any storage medium in other forms known in the art. The storage medium may be coupled to a processor, so that the processor can read information from the storage medium and can write information into the storage medium. Alternatively, the storage medium may be a constituent component of the processor. The processor and the storage medium may be located in an ASIC. The software module may be stored in a memory of a mobile terminal, and may also be stored in a memory card that can be inserted into a mobile terminal. For example, if a device (such as a mobile terminal) uses a large-capacity MEGA-SIM card or a large-capacity flash memory apparatus, then the software modules may be stored in the MEGA-SIM card or the large-capacity flash memory apparatus.

One or more of the functional blocks and/or one or more combinations of the functional blocks shown in the drawings may be implemented as a general-purpose processor, a digital signal processor (DSP), an application-specific integrated circuit (ASIC), a field-programmable gate array (FPGA) or other programmable logic devices, a discrete gate or transistor logic device, a discrete hardware assembly, or any appropriate combination thereof, which is used for implementing the functions described in the present application. The one or more functional blocks and/or the one or more combinations of the functional blocks shown in the drawings may also be implemented as a combination of computing equipment, such as a combination of a DSP and a microprocessor, a plurality of microprocessors, one or more microprocessors in communication combination with a DSP, or any other such configuration.

The present application is described above with reference to specific embodiments. However, it should be clear to those skilled in the art that the foregoing description is merely illustrative and is not intended to limit the scope of protection of the present application. Various variations and modifications may be made by those skilled in the art according to the principle of the present application, and said variations and modifications also fall within the scope of the present application.

1. An isolated resonant power supply circuit, disposed within a scan room of a magnetic resonance imaging system, the isolated resonant power supply circuit comprising: an inverter circuit, a resonant transformer circuit, and a rectifier circuit,
the inverter circuit being connected to the resonant transformer circuit and being used for converting inputted direct current power into alternating current power and outputting the same to the resonant transformer circuit,
the resonant transformer circuit being used for performing resonant conversion and transformation on the alternating current power, and then outputting the same to the rectifier circuit, and
the rectifier circuit being used for rectifying an alternating current output voltage outputted by the resonant transformer circuit into a direct current voltage for output, so as to supply power,
wherein the resonant transformer circuit comprises a variable capacitance circuit and an inductor, and by changing an input voltage of the variable capacitance circuit, an equivalent capacitance value of the variable capacitance circuit is caused to change.

2. The isolated resonant power supply circuit according to claim 1, wherein the variable capacitance circuit comprises a first capacitor, a second capacitor, and a variable resistor, wherein one end of the second capacitor is connected to one end of the variable resistor, the other end of the second capacitor is connected to one end of the first capacitor, and the other end of the first capacitor is connected to the other end of the variable resistor, wherein by changing an input voltage of the variable resistor to change the input voltage of the variable capacitance circuit, the equivalent capacitance value of the variable capacitance circuit is caused to change.

3. The isolated resonant power supply circuit according to claim 2, wherein the variable resistor is a switching transistor operating in a linear region.

4. The isolated resonant power supply circuit according to claim 3, wherein by changing the input voltage of the variable resistor to change a degree of linear conduction of the switching transistor, the equivalent capacitance value of the variable capacitance circuit is caused to change.

5. The isolated resonant power supply circuit according to claim 3, wherein the isolated resonant power supply circuit further comprises: a voltage feedback circuit, used for feeding the direct current voltage outputted by the rectifier circuit back to the variable capacitance circuit; and a feedback voltage of the voltage feedback circuit is used as the input voltage of the variable resistor.

6. The isolated resonant power supply circuit according to claim 5, wherein the voltage feedback circuit is connected to a gate of the switching transistor.

7. The isolated resonant power supply circuit according to claim 5, wherein by changing the feedback voltage, the equivalent capacitance value of the variable capacitance circuit is caused to change between a first value and a second value, wherein the first value is a capacitance value of the first capacitor, and the second value is the sum of capacitance values of the first capacitor and the second capacitor.

8. The isolated resonant power supply circuit according to claim 5, wherein the equivalent capacitance value of the variable capacitance circuit is a second value when the feedback voltage controls the switching transistor to fully turn on, and the equivalent capacitance value of the variable capacitance circuit is a first value when the feedback voltage controls the switching transistor to fully turn off, wherein the first value is a capacitance value of the first capacitor, and the second value is the sum of capacitance values of the first capacitor and the second capacitor.

9. The isolated resonant power supply circuit according to claim 3, wherein the resonant transformer circuit further comprises a third capacitor, one end of the third capacitor is connected to the other end of the first capacitor, and the other end of the third capacitor is connected to a gate of the switching transistor.

10. The isolated resonant power supply circuit according to claim 1, wherein the resonant transformer circuit further comprises an air-cored transformer, the air-cored transformer comprises a bobbin and a first number of windings wound around the bobbin, each winding is formed by winding a wire bundle around the bobbin multiple times, and each wire bundle comprises a second number of winding wires which are twisted together;
wherein a third number of winding wires in each winding serve as a primary winding, two ends of the third number of winding wires are connected to a primary circuit of the air-cored transformer, a fourth number of winding wires in each winding serve as a secondary winding, and two ends of the fourth number of winding wires are connected to a secondary circuit of the air-cored transformer, the first number being an integer greater than or equal to 1, and the second number, the third number, and the fourth number all being integers greater than 1.

11. The isolated resonant power supply circuit according to claim 10, wherein the third number is equal to the fourth number.

12. The isolated resonant power supply circuit according to claim 10, wherein the diameter of each winding wire is less than or equal to a first threshold.

13. The isolated resonant power supply circuit according to claim 10, wherein when the first number is greater than 1, a plurality of primary windings in the first number of windings are connected in series, and a plurality of secondary windings in the first number of windings are connected in parallel.

14. The isolated resonant power supply circuit according to claim 13, wherein all of the secondary windings in the first number of windings pass through rectifiers and are then connected in parallel.

15. The isolated resonant power supply circuit according to claim 10, wherein the first number of windings are all wound in a slot of the bobbin, or the first number of windings are respectively wound in a first number of slots of the bobbin.

16. A magnetic resonance imaging system, comprising:
a main magnet for generating a main magnetic field;
a gradient coil assembly;
a gradient amplifier, used for exciting the gradient coil assembly to generate a gradient magnetic field on a selected gradient axis so as to apply the gradient magnetic field to the main magnetic field;
a radio-frequency coil assembly;
a radio-frequency amplifier for exciting the radio-frequency coil assembly to generate a radio-frequency signal;
the isolated resonant power supply circuit according to claim 1, the isolated resonant power supply circuit being disposed within a scan room of the magnetic resonance imaging system, and supplying power to a device in the scan room.

17. An air-cored transformer, wherein the air-cored transformer comprises a bobbin and a first number of windings wound around the bobbin, each winding is formed by winding a wire bundle around the bobbin multiple times, and each wire bundle comprises a second number of winding wires which are twisted together,
wherein a third number of winding wires in each winding serve as a primary winding, two ends of the third number of winding wires are connected to a primary circuit of the air-cored transformer, a fourth number of winding wires in each winding serve as a secondary winding, and two ends of the fourth number of winding wires are connected to a secondary circuit of the air-cored transformer, the first number being an integer greater than or equal to 1, and the second number, the third number, and the fourth number all being integers greater than 1.

18. The air-cored transformer according to claim 17, wherein when the first number is greater than 1, a plurality of primary windings in the first number of windings are connected in series, and a plurality of secondary windings in the first number of windings are connected in parallel.

19. The air-cored transformer according to claim 18, wherein all of the secondary windings in the first number of windings pass through rectifiers and are then connected in parallel.

20. The air-cored transformer according to claim 17, wherein the first number of windings are all wound in a slot of the bobbin, or the first number of windings are respectively wound in the first number of slots of the bobbin.
